(19) United States
(12) Patent Application Publication
(10) Pub. No.: US 2025/0215639 A1
(43) Pub. Date: Jul. 3, 2025

(54) ELECTRONIC TEXTILES AND SYSTEMS AND PROCESSES ASSOCIATED THEREWITH

(71) Applicant: Purdue Research Foundation, West Lafayette, IN (US)

(72) Inventors: Chi Hwan Lee, West Lafayette, IN (US); Semih Akin, Green Island, NY (US); Taehoo Chang, Beaverton, OR (US); Martin Byung-Guk Jun, West Lafayette, IN (US)

(21) Appl. No.: 18/999,838

(22) Filed: Dec. 23, 2024

Related U.S. Application Data
(60) Provisional application No. 63/616,277, filed on Dec. 29, 2023.

(51) Int. Cl. D06M 15/356; D06M 11/28; D06M 13/355; D06M 23/16; H05K 1/03

(52) U.S. Cl. CPC D06M 15/3562; D06M 11/28; D06M 13/355; D06M 23/16; H05K 1/038; D10B 2401/16; D10B 2501/00; H05K 2201/0329

(57) ABSTRACT

Electronic textiles and systems and processes associated therewith. A dual regime spray system allows the formation of electrically conductive polymers in-situ on the surface of substrates, such as various fabrics. The system mixes atomized streams of a monomer and a polymerization agent for the monomer in a mixing chamber where the polymerization reaction can start and then ejects droplets of the mixed monomer and a polymerization agent out of a nozzle and onto the substrate before the polymerization reaction is fully completed. The polymerization reaction can then complete after the droplets are on the substrate, thereby forming the electrically conductive polymer in-situ on the substrate. The system and process can be used to form electronic textiles that may form various wearable electronic components, such as sensors and luminescent strips, as part of wearable garments.

### CROSS-REFERENCE TO RELATED APPLICATIONS

This application claims the benefit of provisional U.S. Patent Application No. 63/616,277 filed Dec. 29, 2023, the contents of which are incorporated herein by reference.

### BACKGROUND OF THE INVENTION

The present invention generally relates to electronic textiles and systems and processes for their fabrication.

Electronic textiles (also called “e-textiles”) are a form of wearable technology that combines textiles with electrical capabilities, such as sensing elements with sensory capabilities that enable real-time and mobile monitoring of critical health signals. E-textiles are useful for various applications such as wearable healthcare devices, military equipment, and other wearable devices. A range of traditional techniques for overcoating conductive materials onto textiles, such as dip coating, electrochemical deposition, chemical vapor deposition (CVD), physical vapor deposition (PVD), and direct printing, have been developed to produce e-textiles. However, these techniques face challenges in creating intricate or personalized sensor designs for different fabric types due to the requirements of using heat, vacuum, precursors, plasma system, or vaporization process. Additive patterning techniques, such as screen printing, inkjet printing, and three-dimensional (3D) dispensing, have been used to create custom sensor designs on textiles by employing either a shadow mask or direct writing. However, these techniques may encounter challenges with clogging and high-throughput printing, particularly when covering large areas with active nanomaterials or molecules.

E-textiles can also include light-emitting textiles that make use of an electric-powered light-emitting component. The growth of the market for wearable displays has driven the development of electroluminescent threads as light-emitting components, but machine embroidery of electroluminescent threads has been challenging. Traditionally, light-emitting textiles have been created by directly gluing or depositing light-emitting diodes (LEDs) or electroluminescent thin films onto garments. However, these techniques can compromise the flexibility, wearability, and/or washability of the fabric and require difficult conditions to be successfully implemented. Although electroluminescent threads have facilitated the integration of light-emitting textiles on a larger scale, the arrangement of the electroluminescent threads is typically limited to straight lines or rectangular patterns due to the interweaving of conductive fibers. However, current electroluminescent threads are typically unable to meet the strict technical requirements for successful machine embroidery, such as having a high tensile strength of at least 6 N, a moderate elongation at breakpoint below 100%, and a smooth surface finish.

Conductive polymers, such as polypyrrole (PPy), are of particular interest for use in e-textiles because of their mechanical softness, high electrical conductivity, ease of synthesis, compatibility with human skin, and stability against corrosion and oxidation. However, achieving a uniform coating of conductive polymers onto different fabric types with high accuracy presents a challenge due to the nature of the wet polymerization process, which can lead to issues such as aggregation. For example, although reactive inkjet printing has been used for in-situ polymerization on substrates, it faces constraints in scalable patterning due to the lack of efficient and rapid chemical mixing mechanisms. A recent advancement to address this issue is the in-situ aerosol mixing using flow, which allows for compositional mixing of materials with high-throughput printing. However, this technique can also present manufacturing difficulties due to flow disruptions caused by the ongoing changes in viscosity during polymerization.

In view of the above, it would be desirable to have a system that facilitates high-throughput chemical mixing and high-speed spray printing capable of use in the creation of e-textiles. There would also be desirable to be able to incorporate light-emitting e-textiles into fashionable and/or customized designs on consumer fabric items with minimal impact on their desirable properties (e.g., softness, flexibility, durability, water resistance, breathability, etc.) to meet the specific needs of diverse applications.

### BRIEF SUMMARY OF THE INVENTION

The intent of this section of the specification is to briefly indicate the nature and substance of the invention, as opposed to an exhaustive statement of all subject matter and aspects of the invention. Therefore, while this section identifies subject matter recited in the claims, additional subject matter and aspects relating to the invention are set forth in other sections of the specification, particularly the detailed description, as well as any drawings.

The present invention provides, but is not limited to, processes of fabricating electronic textiles, processes of forming an electrically conductive polymer in-situ on substrates, dual regime spray systems, and electronic textiles formed thereby.

According to a nonlimiting aspect of the invention, a process of fabricating an electronic textile includes introducing atomized droplets of a monomer solution into a mixing chamber from a first port, introducing atomized droplets of a polymerization agent for polymerizing the monomer solution into the mixing chamber from a second port, and mixing the atomized droplets of the monomer solution and the polymerization agent in the mixing chamber to initiate a polymerization reaction. Before the polymerization reaction is completed in the mixing chamber, the droplets of the mixed monomer solution and polymerization agent are directed through a deposition nozzle and onto a fabric material where the polymerization reaction is completed to form an electrically conductive polymer on the fabric.

According to another nonlimiting aspect of the invention, a process of forming an electrically conductive polymer in-situ on a substrate includes introducing atomized droplets of a monomer solution into a mixing chamber from a first port, introducing atomized droplets of an oxidizing agent for polymerizing the monomer solution into the mixing chamber from a second port, mixing the atomized droplets of the monomer solution and the oxidizing agent in the mixing chamber to initiate a polymerization reaction, and before the polymerization reaction is completed in the mixing chamber, directing the droplets of the mixed monomer solution and oxidizing agent through a deposition nozzle and onto a substrate where the polymerization reaction is completed to form the electrically conductive polymer in-situ on the substrate.

According to yet another nonlimiting aspect of the invention, a dual regime spray system for forming an electrically conductive polymer in-situ on a substrate includes a mixing chamber with a first inlet port for receiving a flow of an atomized monomer solution and a second inlet port for receiving a flow of an atomized oxidizing agent, and a nozzle for spraying a mixture of the atomized monomer solution and the atomized oxidizing agent onto the substrate. The nozzle is configured to form a tortuous path from each of the first inlet port and the second inlet port to an inlet into the nozzle.

According to still another nonlimiting aspect of the invention, an electronic textile produced by any of the processes described above is provided. The electronic textile may form a wearable sensor and/or a wearable garment.

Technical effects of electronic textiles, elements, systems, and processes as described above preferably include the ability to fabricate custom, high-quality e-textiles with processes that are capable of large-scale production. The electronic textiles, elements, systems, and processes are preferably, though not necessarily, capable of overcoming challenges associated with incorporating e-textiles into medical and consumer fabric items, as a nonlimiting example, as embroiderable electroluminescent threads that meet the requirements of machine embroidery and are compatible with universal embroidery machines, allowing for the creation of customized light-emitting textiles with minimal impact on the fabric properties, facilitating large-scale applications in various fields.

Other aspects and advantages of this invention will be appreciated from the following detailed description in view of the drawings.

### BRIEF DESCRIPTION OF THE DRAWINGS

FIG. 1 is a schematic illustration of a spray head of a dual regime spray system (DRSS that is capable of use in application processes to produce e-textiles according to certain nonlimiting aspects of the invention.

FIG. 2 is a perspective view of the spray head of FIG. 1 installed in a DRSS that implements a CNC machine and control software to control the spray head.

FIG. 3 is a photograph of a pattern formed of polypyrrole (PPy) that was deposited on a white cotton fabric using the DRSS of FIG. 2 in accordance with certain nonlimiting aspects of the invention.

FIG. 4 is a photograph showing a pattern formed of PPy that was programmably deposited on a cotton fabric using the DRSS of FIG. 2 with sub-millimeter resolution.

FIG. 5 is a schematic illustration of a strain sensing element that utilizes two serpentine patterns deposited by the DRSS according to certain nonlimiting aspects of the invention.

FIGS. 6 through 9 are photographs of different wearable sensor applications incorporating e-textiles made with the DRSS according to various nonlimiting embodiments of the invention. FIG. 6 shows an e-textile incorporated into a facial mask. FIG. 7 shows an e-textile incorporated into a cotton glove. FIG. 8 shows an e-textile incorporated into a compression sleeve. FIG. 9 shows an e-textile incorporated into a muscle pressure knee pad.

### DETAILED DESCRIPTION OF THE INVENTION

The intended purpose of the following detailed description of the invention and the phraseology and terminology employed therein is to describe what is shown in the drawings, which relate to one or more nonlimiting embodiments of the invention, and to describe certain but not all aspects of what is depicted in the drawings, including the embodiment(s) to which the drawings relate. The following detailed description also describes certain investigations relating to the embodiment(s) depicted in the drawings, and identifies certain but not all alternatives of the embodiment(s) depicted in the drawings. As nonlimiting examples, the invention encompasses additional or alternative embodiments in which one or more features or aspects shown and/or described as part of a particular embodiment could be eliminated, and also encompasses additional or alternative embodiments that combine two or more features or aspects shown and/or described as part of different embodiments. Therefore, the appended claims, and not the detailed description, are intended to particularly point out subject matter regarded to be aspects of the invention, including certain but not necessarily all of the aspects and alternatives described in the detailed description.

Although the invention will be described hereinafter in some examples in reference to the various types of textiles and garments shown in the drawings, it will be appreciated that the teachings of the invention are also more generally applicable to an even wider variety of types of applications, such as, but not limited to e-textiles to be worn by humans and/or other animals, different electrical circuits, different electronic couplings, and use with different electronic devices. In addition, unless otherwise indicated, the term e-textile is not limited to only traditional woven cloth textiles, but may include any type of flexible fabric material used for clothing, including by way of nonlimiting examples, woven fabrics of natural and/or synthetic materials, non-woven fabrics, such as blown fiber fabrics and felts, leather and other natural fabrics, and other non-woven fabrics such as flexible rubber films and polymer films.

As used herein the terms “a” and “an” to introduce a feature are used as open-ended, inclusive terms to refer to at least one, or one or more of the features, and are not limited to only one such feature unless otherwise expressly indicated. Similarly, use of the term “the” in reference to a feature previously introduced using the term “a” or “an” does not thereafter limit the feature to only a single instance of such feature unless otherwise expressly indicated

Electronic textiles (“e-textiles”) and electrical elements, including sensing elements and electroluminescent threads, that are capable of being realized therewith are disclosed, as well as processes and systems for incorporating electrical elements into e-textiles. In some embodiments, e-textiles and an additive patterning process that utilizes a dual-regime spray system (DRSS) to produce e-textiles that incorporate electrical elements made of electrically conductive polymers are provided. The e-textiles may have electrical components including, but not limited to, electrical sensing elements and electroluminescent threads. In some arrangements, processes of using the DRSS (also referred to as DRSS process or DRSS processes) can eliminate the need for masks and allows programmable inscription/printing of electrical elements onto medical and consumer fabrics. Unlike traditional spray techniques, the process enables in-situ, on-the-fly polymerization of electrically conductive polymers, enabling the production of intricate designs with sub-millimeter resolution across fabric areas spanning several meters. Moreover, the process may in some configurations mitigate nozzle clogging problems commonly encountered in such applications. The resulting e-textiles may preserve essential fabric characteristics, such as breathability, wearability, and washability, while delivering exceptional sensing performance.

In addition, various electrical elements and e-textiles fabricated with such elements using the DRSS are also disclosed. The e-textiles and electrical elements can be fabricated using universal embroidery machines and are compatible with various consumer fabrics. The threads may exhibit and maintain a light-emitting performance and withstand wear and tear. The electrical elements can be used to produce sensing elements and/or decorative designs having predetermined patterns, providing a toolkit for creating customized e-textiles that cater to diverse flexible and wearable medical and display needs. Nonlimiting example applications include sensing elements incorporated into wearable healthcare, military, and garments, illuminated messages or designs on consumer goods, and emergency alerts on helmet liners.

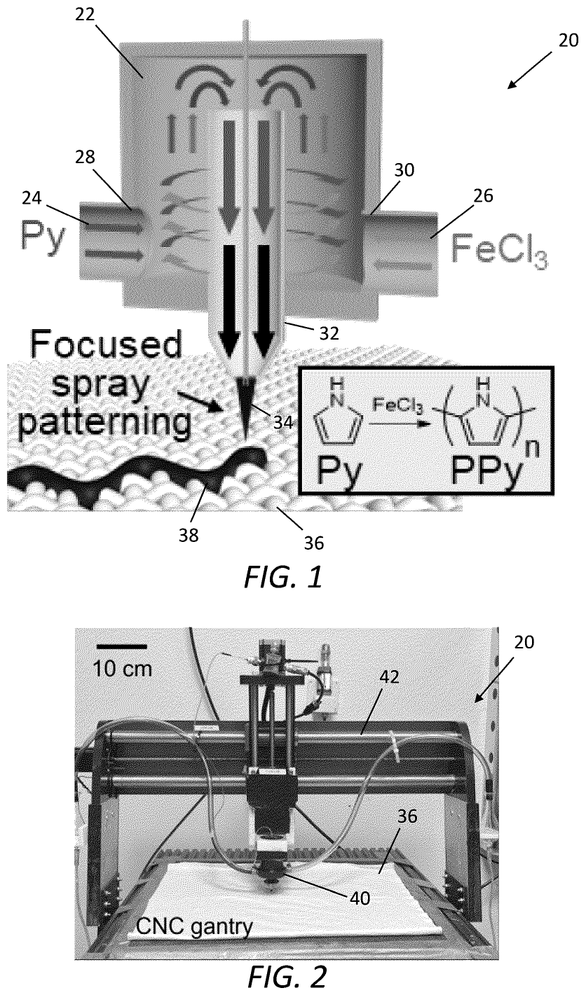

Turning now to the drawings, FIG. 1 schematically illustrates a portion of a DRSS 20 and a spray application process (e.g., printing and/or additive manufacturing) that can be implemented with the DRSS to manufacture e-textiles. The DRSS 20 includes a mixing chamber 22 in which a monomer solution 24 and a polymerization agent 26 for polymerizing the monomer of the monomer solution 24 are mixed. A first inlet port 28 into the mixing chamber 22 is used to introduce a first supply of the monomer solution 24. A second inlet port 30 into the mixing chamber 22 is used to introduce a second supply of the polymerization agent 26 separately from the monomer solution 24. A nozzle 32 serves as an exit port from the mixing chamber 22 to allow the monomer solution 24 and/or the polymerization agent 26 to be ejected from inside the mixing chamber 22 in a selected direction. In this example, the nozzle 32 includes a tube portion that extends inwardly from an interior wall of the mixing chamber 22 and a spray tip portion disposed on the exterior of the mixing chamber 22. The tube portion is disposed in a central area of the mixing chamber 22 so that the monomer solution 24 and/or the polymerization agent 26 will follow a swirling and/or other tortuous path around the tube portion to promote intermixing and atomization before entering an inlet into the nozzle 32. The spray tip portion is configured to focus a spray stream 34 of the mixed monomer solution 24 and polymerization agent 26 onto a target substrate, such as a fabric 36. The mixing chamber 22 is substantially closed such that a desired level of atomization pressure can be developed inside the mixing chamber 22 as the monomer solution 24 and/or the polymerization agent 26 travel from the inlet ports 28 and 30 to the inlet of the nozzle 32. The mixing chamber 22 may be provided with additional inlet ports 28 and/or 30 if desired, for example, to increase the supply rate of the monomer solution 24 and/or the polymerization agent 26 and/or control the flow patterns, input velocities, and/or mixing characteristics of the flow of the monomer solution 24 and/or the polymerization agent 26 inside the mixing chamber 22.

In this example, the monomer solution 24 contains the monomer Py, and the polymerization agent 26 contains FeCl₃ as an oxidizing polymerization agent; however other monomers and polymerization agents may be used. By way of some nonlimiting examples, respective monomers and oxidizer polymerization agents could be used suitable to form not only polypyrrole (PPy), but also conductive polymers such as polyaniline (PANI), poly(3,4-ethylenedioxythiophene) polystyrene sulfonate (PEDOT), and/or polythiophene (PTh). Thus, the monomers and oxidizers may include pyrrole (Py) and iron (III) chloride (FeCl₃) for PPy, aniline (C₆H₅NH₂) and ammonium persulfate ((NH₄)₂S₂O₈) for PANI, 3,4-ethylenedioxythiophene (EDOT) and FeCl₃ with polystyrene sulfonate (PSS) for PEDOT, and thiophene (C₄H₄S) and FeCl₃ for PTh.

In operation, each of the monomer solution 24 and the polymerization agent 26 is introduced into the mixing chamber 22 along with a carrier gas, such as air, at a velocity and under a pressure sufficient to atomize both streams of the monomer solution 24 and the polymerization agent 26 into tiny droplets as they travel into and/or along the tortuous path through mixing chamber 22 to the inlet of the nozzle 32. The monomer solution 24 and the polymerization agent 26 may be delivered via hoses, pipes, or other suitable transport mechanisms from suitable sources, such as tanks or other containers. The monomer solution 24 and the polymerization agent 26 may be mixed with a carrier gas and then atomized by any suitable method and with any suitable atomizer, such as a venturi disposed in or upstream from each of the first and second inlet ports 28 and 30. Typically, the monomer solution 24 includes the selected monomer dissolved in a suitable solute sufficient to allow ready atomization and fluidic flow through the mixing chamber 22 and out the nozzle 32. Similarly, the polymerization agent 26 is provided in the form of an oxidizer solution of a suitable oxidizing agent and solute to promote atomization and fluidic flow. The monomer solution 24 and the polymerization agent 26 are introduced into the mixing chamber 22 at a first velocity using low-speed airflow, typically less than about 10 m/s. As the atomized monomer solution 24 and the polymerization agent 26 mix together within the mixing chamber 22, an oxidative polymerization reaction of the monomer of the monomer solution 24 begins to occur. When the flow enters the nozzle 32 from the mixing chamber 22, the velocity of the flow increases to a second, higher velocity and is ejected out the tip portion, which further accelerates the polymerization reaction. The velocity of the flow through the mixing chamber 22 into the nozzle 32 and eventually out the tip portion is preferably high enough that complete polymerization of the atomized monomer solution 24 and the polymerization agent 26 does not occur until after the mixture has exited the tip portion, and typically not until after the mixture has landed on the surface of the target fabric 36. In this way, the DRSS 20 prevents clogging of the nozzle 32, the mixing chamber 22, and the inlet ports 28 and 30 by preventing agglomeration of cured polymeric material inside the DRSS 20.

As shown in FIG. 2, the mixing chamber 22 and the nozzle 32 may be provided in the form of a spray head 40 that can be readily moved across the surface of the fabric 36 in a controlled manner (e.g., velocity, direction, distance from surface, etc.) so that predefined patterns 38 of the ejected mixture from the nozzle 32 can be deposited on to the surface of the fabric 36. In some embodiments, the DRSS 20 may include various control components for controlling movement of the spray head 40 and/or flow characteristics of the atomized monomer solution 24 and the polymerization agent 26 through the mixing chamber 22 and the nozzle 32. For example, the spray head 40 may be attached to a gantry of a three-axis computer numerical control (CNC) machine 42 and movement of the spray head 40, as well as flow velocity, pressure, etc., controlled by a computer program to print patterns of high complexity and high accuracy onto the fabric 36. Such patterns may include, without limitation, various electrical circuit components for sensors (e.g., motion sensors, strain sensors, heat sensors, etc.), light emitting circuits, heat emitting circuits, stimulation circuits, and antennas. Other control components may be used in addition to or in lieu of the CNC machine 42 as suitable for depositing desired patterns onto the surfaces of various substrates. Thus, the DRSS 20 can be used to apply highly complicated and detailed patterns of electrically conductive polymers onto fabrics to form e-textiles that can be adapted for use in a nearly infinite variety of configurations and purposes. The DRSS 20 and processes performed with the DRSS 20 generate numerous micro-reactive droplets simultaneously and can achieve high-throughput chemical mixing and high-resolution spray printing.

Investigations, combining experimental, computational, and theoretical approaches, were conducted to examine the critical factors influencing the operation of the DRSS 20 and its role in e-textile fabrication. The DRSS 20 shown in FIG. 2 was utilized during the investigations to produce e-textiles from fabric items by performing in-situ, on-the-fly spray polymerization of a conductive polymer on various fabrics. In the nonlimiting investigations, the conductive polymer was polypyrrole (PPy) synthesized by oxidative polymerization of pyrrole (Py) monomer in the monomer solution 24 using iron (III) chloride hexahydrate (FeCl₃·6H₂O) as a chemical oxidant in the polymerization agent 26. However, those skilled in the art will appreciate that a larger variety of conductive polymers can be formed by polymerization of monomers using polymerization agents based on the principles disclosed herein.

The kinetics of the spray polymerization can be readily controlled to tune the electrical conductivity of the conductive polymers formed by the DRSS 20. Proof-of-concept demonstrations included directly spraying conductive polymers into custom designs of stretchable strain gauges, with a gauge factor (GF) of over 85, onto various garments such as masks, gloves, and stockinettes. These e-textiles were capable of continuously and unobtrusively tracking a range of human body movements from subtle (e.g., breathing) to large (e.g., joint bending) movements, while minimally affecting the inherent fabric properties such as wearability, breathability, and washability.

For the investigations, two pneumatic glass atomizers (ArOmis Inc.) were used to prepare a solution of 2M Py (Sigma-Aldrich) in methanol and a solution of 500 mM FeCl₃·6H₂O (Sigma-Aldrich) in a 1:7 v/v mixture of water and methanol. Droplets of the atomized monomer and oxidant were fed into the mixing chamber 22 of the DRSS 20 using low-speed airflow (less than 10 m/s) where droplets of the atomized Py and FeCl₃ contacted each other, and the polymerization process was initiated to form PPy nanoparticles. The polymerization process was further accelerated by the central airflow within a nozzle 32 of the mixing chamber 22 and finally completed as the PPy nanoparticles were sprayed onto surfaces of fabrics 36. The DRSS 20 integrated at least two different air flow modules: a low-speed air flow module that facilitated the atomization of the Py monomer and the FeCl₃·6H₂O oxidant entering the mixing chamber 22; and a high-speed air flow module that passes through the nozzle 32. Each atomization pressure was adjusted from 40 to 120 kPa. To mitigate the potential issue of the Py monomer reacting or changing its properties during atomization, each atomization pressure was adjusted and maintained above 40 kPa, which facilitated optimal aerosol mixing of the monomer and oxidant and efficient polymerization of the Py to PPy. The high-speed central air flow was maintained at a velocity of 100 m/s during spraying.

Oxygen plasma-treated stretchable cotton fabric 36 was placed at a distance of about 2 mm from the exit of the nozzle 32. The highest speed of linear travel of the nozzle 32 while spraying the PPy was about 50 cm/min. The DRSS 20 was mounted on the three-axis computer numerical control (CNC) gantry 42, which was controlled by conventional computer controls to cause the nozzle 32 to draw programmed patterns. Polymerization of Py to PPY was visually observed by the black color of the resulting PPy. Fabrics 36 with PPy deposited thereon were rinsed with water and dried at room temperature.

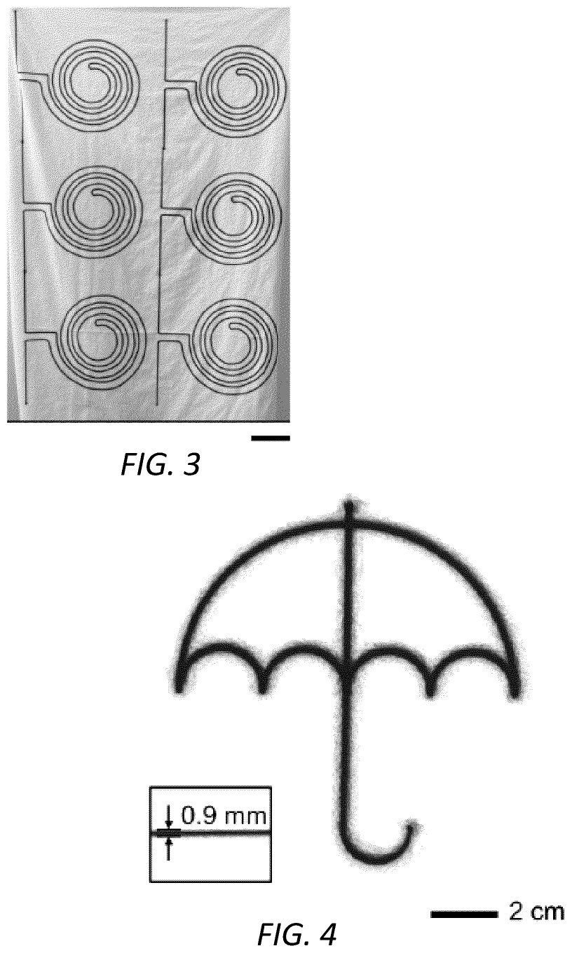

The DRSS 20 and process evaluated during the investigations were determined to offer several key advantages over existing spraying techniques. As illustrated by the patterns achieved in FIGS. 3 and 4, the investigations showed that the DRSS 20 was able to produce fine lines (less than 1 mm width) of electrically conducive polymer in relatively complicated patterns at larger scale (e.g. centimeter to meter scale). For example, as shown in FIG. 3, the DRSS process was scalable at over meter scale with reasonable reproducibility. Serpentine lines at millimeter scale widths and centimeter scale lengths of PPy that were sprayed onto different fabrics using the DRSS 20 exhibited complete polymerization of PPy. In addition, the DRSS 20 did not require the use of a precursor coating, vacuum chamber, or heat treatment, making it compatible with a wide range of natural and synthetic fabric types. As shown in FIG. 4, the DRSS process was able to produce intricate designs, such as an umbrella shape, with sub-millimeter resolution without needing a shadow mask. The resolutions of the resulting deposited patterns 38 were determined by four key operational conditions: atomization pressure, nozzle transverse speed, central air velocity, and spray distance to fabric. While using a shadow mask offers an alternative for achieving high resolution, it necessitates constant fabrication with each pattern change. The DRSS 20, through computer programmable patterning, was capable of ensuring consistent coating quality on textiles by facilitating high mass loading and deep penetration coating through the fabric thickness. Moreover, the DRSS process was determined to induce minimal risk of contamination and clogging inside the DRSS mixing chamber 22 and nozzle 32 after prolonged use. This was concluded to be due to its unique working principle that involves two atomizers that mix reactive chemicals in atomized states within the mixing chamber 22. The chemicals are swiftly propelled through the nozzle 32 by air flow, ensuring that the chamber 22 and nozzle 32 remained uncontaminated.

In a further investigation, a nozzle 32 was prepared using resin and utilized for an extended period of time (greater than 90 minutes). The nozzle 32 turned slightly blackish after ninety minutes of usage, but no signs of clogging were observed. The nozzle 32 was able to provide uniform and uninterrupted coating of PPy over the entire surface of fabric yarns without agglomeration, in comparison to those using a conventional airbrush. Additional scanning electron microscope (SEM) images not only corroborated consistent results but also substantiated the absence of any corrosion or alterations in the morphology of the fabric surface. FT-IR analysis confirmed that the PPy synthesized through the DRSS 20 has similar qualities to that of PPy synthesized through conventional dip-coating methods. Furthermore, for in-situ spray polymerization, the DRSS process was determined to be versatile and adaptable for other conductive polymers. For instance, polyaniline (PANI), known for its high conductivity, environmental stability, and biocompatibility, was successfully polymerized and directly written onto cotton fabric using the DRSS process.

Implementing suitable spray conditions for operation of the DRSS process is advantageous for successful in-situ, on-the-fly polymerization of the PPy (or other electrically conductive polymer). Operational parameters that are believed to be particularly relevant to effective implementation of the DRSS 20 include the number of spray passes (N_{P}), nozzle transverse velocity (V_{N}), atomization pressure (P_{A}), and carrier gas flow in the mixing chamber 22. Investigations of the atomization flow rates of Py and FeCl₃ over a range of P_{A} between 40 and 120 kPa showed that as the P_{A} increased, the atomization flow rate also increased and reached its maximum value (approximately 16 μL s⁻¹ for Py and 10 μL s⁻¹ for FeCl₃) at P_{A}=120 kPa. This indicated that a higher amount of reactive chemical agents was carried into the mixing chamber 22 with the increased P_{A}. A higher atomization flow rate observed in Py as compared to FeCl₃ was believed to be attributable to the substantially lower viscosity of Py (6.22×10⁻⁴ Pa s) relative to FeCl₃ (2.25×10⁻³ Pa s). The increased P_{A} led to a greater quantity of atomized Py and FeCl₃, as well as improved mixing inside the chamber. These factors led to accelerated polymerization and reduced resistance.

The impact of P_{A} (60-120 kPa) and V_{N} (10-50 cm/min) on the mass loading of PPy sprayed onto a cotton fabric was also observed during these investigations. The mass loading of PPy exhibited an increase with increasing P_{A}, reaching a maximum value of approximately 87 mg cm⁻¹ at P_{A}=120 kPa and V_{N}=10 cm min⁻¹. At this point, the corresponding R_{PPy} was measured as 1.6 kΩ at N_{P}=10 passes. Conversely, when sprayed using a conventional airbrush, the resistance of PPy (R_{PPy}) remained considerably higher even at N_{P}=20 passes due to widespread dispersion and low mass load of PPy.

The effect of N_{P} and V_{N} on the R_{PPy} over a range of N_{P}=1-20 passes and V_{N}=10-50 cm/min was also observed. The investigations showed that the R_{PPy} tended to decrease as N_{P} increased or V_{N} decreased. The investigations also showed that the increased P_{A} resulted in a decrease in R_{PPy}. In addition, by adjusting the P_{A} during the DRSS 20, the R_{PPy} can be varied between 1.6-89.3 kΩ. To demonstrate this feature, four resistive heaters were sprayed onto a cotton fabric with the same width (6 mm) and serpentine shape but varying P_{A}=90-120 kPa. This resulted in a range of R_{PPy} from 0.8 to 3.3 kΩ, or a range of heat generation levels from 36 to 55° C. at an applied voltage of 30 V. The patterns also demonstrated consistent resistance (R_{PPy}=5.05±0.17 kΩ) across several test specimens, highlighting minimal variations using the DRSS 20 and emphasizing the dependable polymerization and patterning capabilities of the DRSS 20 and process.

Computational fluid dynamics (CFD) modeling predicted that as the P_{A} increases from 40 kPa to 120 kPa, the carrier gas flow inside the mixing chamber 22 becomes more uniform, resulting in improved mixing and polymerization of PPy. These CFD results were consistent with experimental data, indicating that the PPy was fully polymerized at P_{A}=120 kPa, whereas incomplete polymerization was observed at P_{A}=40 kPa. The P_{A} for both Py and FeCl₃ was balanced to prevent non-uniform carrier gas flow in the mixing chamber 22. The concentration ratio to Py and FeCl₃ was maintained at 4:1 to provide the lowest R_{PPy} (54.3±5.1 kΩ). Methanol (MeOH) was used as a mixing solvent for both Py and FeCl₃, resulting in a nearly four-fold lower R_{PPy} compared to those obtained when using water (H₂O) and other polar solvents such as ethanol (EtOH). This is believed to be attributable to the unique interaction between Py and MeOH, including their high miscibility, lower boiling point of Py, faster evaporation rate, and polarity, as well as the ability of MeOH to reduce Coulomb interaction during polymerization. Taken all together, optimal conditions of this particular investigated DRSS process achieved highly uniform and conductive applied PPy patterns when the P_{A}=120 kPa, N_{P}=10 passes, and V_{N}=10 cm/min., using a MeOH mixing solution with a Py:FeCl₃ concentration ratio of 4:1. Of course, the optimal conditions may vary depending many other factors, such as the type of fabric used as a substrate, the type of monomer, the type of oxidizer, type of solute, environmental factors, and desired form of the final applied pattern 38.

In some embodiments, an overcoat of silicone sealer, such as Ecoflex™ 00-30 diluted in Silicone Thinner™, may be applied over the pattern 38 of the electrically conductive polymer. Preferably, the silicone sealer fully encapsulates the pattern 38. The silicone sealer can be applied by any suitable application method, such as with a brush, roller, or sprayer. The silicone sealer overcoat is preferably applied after the monomer applied to the fabric 36 has completely polymerized. The overcoating of silicone sealer can improve durability of the pattern 38 under repeated strain loading-unloading cycles and temperature change cycles, as well as over multiple washing cycles and environmental factors, such as sweating. The silicone sealer may also at least partially resist incursion of moisture and/or other surrounding environmental matter, such as sweat or laundry detergent, on the pattern 38.

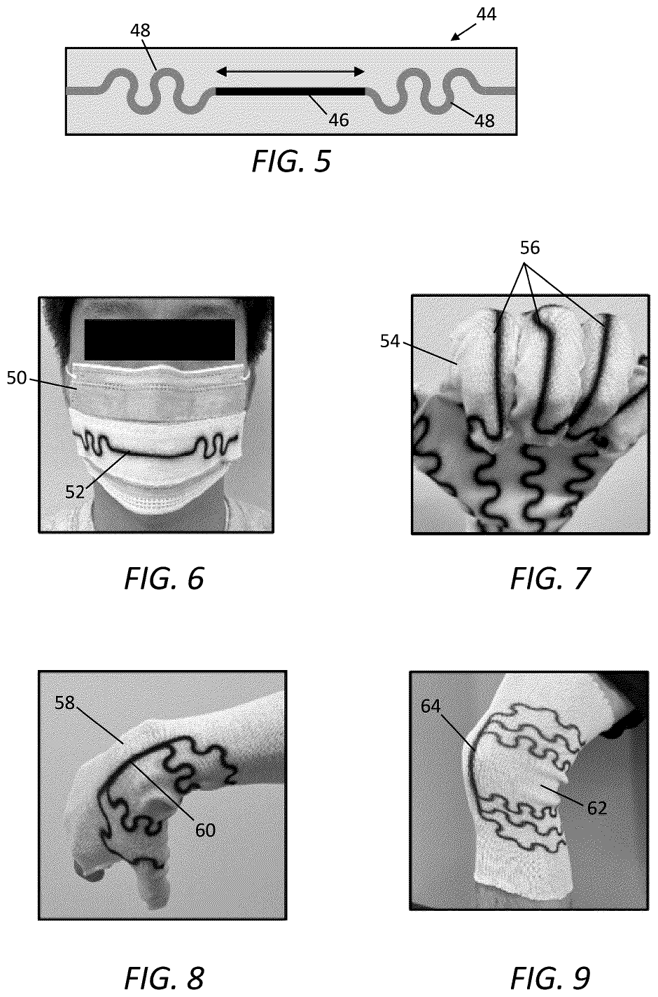

In some embodiments, the pattern 38 can be configured to create a stretchable strain sensor on the fabric 36. For example, as illustrated by the strain gauge shown in FIG. 5, a strain gauge 44 having highly strain-responsive straight lines of the electrically conductive polymer can be applied in the target location of the sensing area in conjunction with strain-insensitive serpentine lines as interconnectors. In this nonlimiting example, the strain gauge 44 is made using the DRSS 20 and process and includes a straight line strain sensing region 46 with a serpentine interconnector 48 extending from each opposite end of the straight strain sensing region. Of course, because of the versatility of the DRSS 20, many other sensor shapes, as well as other electrical components such as stimulators, antennae, heaters, etc. could be made in a similar manner.

Continuous and unobtrusive monitoring of strains, ranging from minor (less than 5%) to substantial (10-40%), in various body motions is of particular interest not only for understanding the mechanics of human movements, joint responses, and fatigue, but also for aiding in the prevention and recovery of musculoskeletal injuries and disorders. The DRSS 20 and its associated process can be used to make a wide variety of sensors on a wide variety of wearable items made with the e-textiles. Some nonlimiting examples of such wearable sensors are shown in FIGS. 6-9, which illustrate different strain gauges prepared by spraying PPy across a range of consumer fabrics using the DRSS 20. FIG. 6 illustrates a non-woven 3-ply facial mask 50 with a strain gauge 52 formed thereon using the DRSS 20 and process disclosed herein. The mask 50 can be used, for example, for continuous monitoring of respiration rate. FIG. 7 illustrates a white cotton glove 54 with several strain gauges 56 formed thereon using the DRSS 20 and process. The glove 54 can be used, for example, for continuous monitoring of finger curl. FIG. 8 illustrates a compression sleeve (wrist stockinette) 58 with several strain gauges 60 formed thereon using the DRSS 20 and process. The compression sleeve 58 can be used, for example, for continuous monitoring of wrist rotation. FIG. 9 illustrates a muscle pressure knee wrap (cotton stockinette roll) 62, with several strain gauges 64 formed thereon using the DRSS 20 and process. The knee wrap 62 may be used, for example, for continuous monitoring of knee flexion. As illustrated by these examples, the DRSS 20 and the process disclosed herein can be used to make complex designs of strain sensor arrays on various types of commercial garments. Such garments can be used to monitor various different body movements on the skin using the sensors. Ergonomic designs of the consumer fabrics can ensure that the wearable sensors fit tightly to the different body parts and follow body motions accurately, resulting in high fidelity recordings of strains with large signal-to-noise ratios (greater than 28.6 dB). To elaborate on human body movement through strain sensor measurement, time-frequency analysis and spectral data were implemented. Wearable sensors made in this manner can detect small body movements, such as respiration and small joint movement (finger) and exhibit various frequency components (0-5 Hz) with low signal amplitude, as well as substantial body motions, like wrist and knee movement, characterized by dominant low-frequency signal components (less than 1.5 Hz) with strong signal amplitude. Advantageously, such wearable sensors can provide improved wearability characteristics, for example, by reducing or eliminating skin irritation of the wearer.

The DRSS 20 and process provide a promising method of additive patterning that can be used to quickly transform traditional clothing into personalized e-textiles, while minimally affecting the intrinsic characteristics of the clothing. The programmable DRSS 20 can be used to perform in-situ, on-the-fly polymerization of conductive polymers, such as PPy, allowing direct spray writing of custom designs—from basic to complex patterns—for strain gauges, as well as many other types of electrical components. The DRSS 20 and process can achieve high resolution (e.g., down to at least 0.9 mm line width), high sensitivity (e.g., GF=85.15), high scalability (e.g., over a meter), and low electrical resistance (e.g., less than 1.6 kΩ). The DRSS 20 and process can also be used to form a seamless coating of electrically conductive polymers without nozzle blockage. The evenly distributed electrically conductive polymers across the yarns or other fibers of the fabrics allow the resulting e-textiles to maintain their mechanical flexibility, breathability, and wearability. When used on stretchable clothing, the e-textiles can provide a comfortable fit, enabling precise strain monitoring across a wide spectrum, from subtle to substantial body movements.

In addition to the various example configurations and use scenarios described herein, e-textiles manufactured using the DRSS 20 and processes disclosed herein hold immense potential in consumer markets such as interactive fashion, safety gear, and entertainment, offering opportunities for real-time environmental and biometric monitoring, dynamic user interaction, and immersive experiences. The DRSS 20 and processes offer new avenues for the creation of personalized e-textiles, bringing together custom functionality and stylish designs.

As previously noted above, though the foregoing detailed description describes certain aspects of one or more particular embodiments of the invention and investigations associated with the invention, alternatives could be adopted by one skilled in the art. For example, the e-textiles, threads and devices associated therewith could differ in appearance and construction from what is described herein and shown in the figures, functions of certain components could be performed by components of different construction but capable of a similar (though not necessarily equivalent) function, process parameters such as temperatures and durations could be modified, and appropriate materials could be substituted for those noted. As such, and again as was previously noted, it should be understood that the invention is not necessarily limited to any particular embodiment described herein or illustrated in the drawings.

1. A process of fabricating an electronic textile, the process comprising:
introducing atomized droplets of a monomer solution into a mixing chamber from a first port;
introducing atomized droplets of a polymerization agent for polymerizing the monomer solution into the mixing chamber from a second port;
mixing the atomized droplets of the monomer solution and the polymerization agent in the mixing chamber to initiate a polymerization reaction; and
before the polymerization reaction is completed in the mixing chamber, directing the droplets of the mixed monomer solution and polymerization agent through a deposition nozzle and onto a fabric material where the polymerization reaction is completed to form an electrically conductive polymer on the fabric.

2. The process of claim 1, wherein the process is performed with a dual regime spray system and the process comprises:
passing the monomer solution and the polymerization agent through the mixing chamber at a first air flow speed to promote the mixing; and
passing the droplets through the deposition nozzle at a second air flow speed that is greater than the first airflow speed to spray a focused stream of the droplets onto the fabric material.

3. The process of claim 1, wherein the step of atomizing and mixing comprises applying different atomization pressures to the monomer solution and the polymerization agent to atomize the monomer solution and the polymerization agent entering the mixing chamber.

4. The process of claim 1, wherein the steps of introducing include mixing each of the monomer solution and the polymerization agent with a carrier gas.

5. The process of claim 1, wherein the droplets deposited on the fabric material form an electrically conductive element having a predetermined pattern.

6. The process of claim 5, wherein the electrically conductive element comprises at least one of a sensing element and an electroluminescent thread.

7. The process of claim 1, wherein the conductive polymer comprises polypyrrole (PPy) synthesized by oxidative polymerization of pyrrole (Py) monomer in the monomer solution using iron (III) chloride hexahydrate (FeCl₃·6H₂O) as a chemical oxidant in the polymerization agent.

8. The process of claim 1, wherein the electrically conductive polymer comprises at least one of polypyrrole (PPy), polyaniline (PANI), poly(3,4-ethylenedioxythiophene) polystyrene sulfonate (PEDOT), and polythiophene (PTh).

9. A process of forming an electrically conductive polymer in-situ on a substrate, the process comprising:
introducing atomized droplets of a monomer solution into a mixing chamber from a first port;
introducing atomized droplets of an oxidizing agent for polymerizing the monomer solution into the mixing chamber from a second port;
mixing the atomized droplets of the monomer solution and the oxidizing agent in the mixing chamber to initiate a polymerization reaction; and
before the polymerization reaction is completed in the mixing chamber, directing the droplets of the mixed monomer solution and oxidizing agent through a deposition nozzle and onto a substrate where the polymerization reaction is completed to form the electrically conductive polymer in-situ on the substrate.

10. The process of claim 9, wherein the process is performed with a dual regime spray system and the process comprises:
passing the monomer solution and the oxidizing agent through the mixing chamber at a first air flow speed to promote the mixing; and
passing the droplets through the deposition nozzle at a second air flow speed that is greater than the first airflow speed to spray a focused stream of the droplets onto the substrate.

11. The process of claim 9, wherein the step of atomizing and mixing comprises applying different atomization pressures to the monomer solution and the oxidizing agent to atomize the monomer solution and the oxidizing agent entering the mixing chamber.

12. The process of claim 9, wherein the steps of introducing include mixing each of the monomer solution and the oxidizing agent with a carrier gas and the step of mixing comprises directing the carrier gas through the mixing chamber in a tortuous path before entering the nozzle.

13. A dual regime spray system for forming an electrically conductive polymer in-situ on a substrate, the dual regime spray system comprising:
a mixing chamber with a first inlet port for receiving a flow of an atomized monomer solution and a second inlet port for receiving a flow of an atomized oxidizing agent; and
a nozzle for spraying a mixture of the atomized monomer solution and the atomized oxidizing agent onto the substrate,
wherein the nozzle is configured to form a tortuous path from each of the first inlet port and the second inlet port to an inlet into the nozzle.

14. The dual regime spray system of claim 13, wherein the tortuous path comprises a swirling path around a tube portion of the nozzle that extends into the mixing chamber.

15. The dual regime spray system of claim 13, further comprising a first atomizer for atomizing the monomer solution upstream of the mixing chamber and a second atomizer for atomizing the oxidizing agent upstream of the mixing chamber.

16. The dual regime spray system of claim 13, wherein the nozzle comprises a spray tip for generating a focus spray directed outside of the mixing chamber.

17. The dual regime spray system of claim 13, further comprising a monomer solution provided to the first inlet port and an oxidizing agent provided to the second inlet port.

18. The dual regime spray system of claim 17, further comprising a carrier gas for carrying the monomer solution and the oxidizing agent to the respective first and second inlet ports, through the mixing chamber, and out the nozzle.

19. The dual regime spray system of claim 18, further comprising a computer controller for controlling movement of a spray head comprising the mixing chamber and the nozzle over a surface of a substrate.

20. An electronic textile produced by the process of claim 1, wherein the electronic textile comprises a wearable sensor.

21. The electronic textile of claim 20, wherein the electronic textile comprises a wearable garment.
